(19) United States
(12) Patent Application Publication
(10) Pub. No.: US 2020/0050036 A1
(43) Pub. Date: Feb. 13, 2020

(54) DISPLAY DEVICE

(71) Applicant: Sharp Kabushiki Kaisha, Sakai City (JP)

(72) Inventors: Keiichi INA, Sakai City (JP); Yasuyoshi KAISE, Sakai City (JP)

(21) Appl. No.: 16/529,868

(22) Filed: Aug. 2, 2019

Related U.S. Application Data
(60) Provisional application No. 62/717,012, filed on Aug. 10, 2018.

(51) Int. Cl. G02F 1/1368; G02F 1/1362; G02F 1/1343; G02F 1/1339; H01L 27/12; H05K 1/18

(52) U.S. Cl. CPC G02F 1/1368; G02F 1/136209; G02F 1/136286; G02F 1/134309; H05K 2201/10136; H01L 27/124; H05K 1/189; G02F 2001/136222; G02F 2201/123; G02F 1/1339

(57) ABSTRACT

A display device includes a first substrate, a second substrate disposed opposite the first substrate, pixels arranged in a matrix within a plate surface of the first substrate and the second substrate, a first line disposed on the second substrate and extending in a first direction along the plate surface, a first light blocking section disposed on the first substrate and between the pixels that are next to each other in the first direction and extending in a second direction that is along the plate surface and crosses the first direction, and a second light blocking section disposed on the second substrate and between the pixels that are next to each other in the second direction, extending in the first direction, and overlapping the first line.

### CROSS REFERENCE TO RELATED APPLICATION

This application claims priority from U.S. Provisional Patent Application No. 62/717,012 filed on Aug. 10, 2018. The entire contents of the priority application are incorporated herein by reference.

### TECHNICAL FIELD

The present technology described herein relates to a display device.

### BACKGROUND ART

One example of display devices described in Japanese Unexamined Patent Application Publication No. 2015-135531 has been conventionally known. The display device includes a film including two coloring layers (a multi-layered film including a red coloring layer and a blue coloring layer or a multi-layered film including a red coloring layer and a green coloring layer) as a light blocking section on a counter substrate such that the film overlaps a TFT of a component substrate.

According to the display device, a light blocking mask (a black matrix) is not necessary and this reduces the number of producing processes. However, in the display device, the coloring layers exhibiting different colors are stacked on each other to block light. According to such a structure, the light blocking properties may not be sufficient and light leaking is likely to be caused and contrast properties are likely to be lowered due to the light leaking compared to the light blocking mask.

### SUMMARY

The technology described herein was made in view of the above circumstances. An object is to restrict lowering of contrast properties.

A display device according to the technology described herein includes a first substrate, a second substrate that is disposed opposite the first substrate, pixels arranged in a matrix within a plate surface of the first substrate and the second substrate, a first line disposed on the second substrate and extending in a first direction along the plate surface, a first light blocking section disposed on the first substrate and between the pixels that are next to each other in the first direction and extending in a second direction that is along the plate surface and crosses the first direction, and a second light blocking section disposed on the second substrate and between the pixels that are next to each other in the second direction, extending in the first direction, and overlapping the first line.

According to the technology described herein, lowering of contrast properties is less likely to be caused.

### BRIEF DESCRIPTION OF THE DRAWINGS

FIG. 1 is a schematic plan view illustrating a connection structure of a liquid crystal panel, a flexible circuit board, and a control circuit board included in a liquid crystal display device according to a first embodiment.

FIG. 2 is a schematic plan view illustrating pixel arrangement in a display area of an array substrate included in the liquid crystal panel.

FIG. 3 is a schematic plan view illustrating pixel arrangement in a display area of a CF substrate included in the liquid crystal panel.

FIG. 4 is a plan view illustrating a wiring configuration in the display area of the array substrate.

FIG. 5 is a plan view illustrating a configuration in a display area of the CF substrate.

FIG. 6 is a cross-sectional view of the liquid crystal panel taken along line A-A in FIG. 4.

FIG. 7 is a cross-sectional view of the liquid crystal panel taken along line B-B in FIG. 4.

FIG. 8 is a cross-sectional view of the liquid crystal panel taken along line C-C in FIG. 4.

FIG. 9 is a cross-sectional view of the liquid crystal panel taken along line D-D in FIG. 4.

FIG. 10 is a plan view of schematically illustrating pixel arrangement in a display area of an array substrate included in a liquid crystal panel according to a second embodiment.

FIG. 11 is a plan view of schematically illustrating pixel arrangement in a display area of an array substrate included in a liquid crystal panel according to a third embodiment.

FIG. 12 is a plan view of schematically illustrating pixel arrangement in a display area of an array substrate included in a liquid crystal panel according to a fourth embodiment.

FIG. 13 is a plan view of schematically illustrating pixel arrangement in a display area of an array substrate included in a liquid crystal panel according to a fifth embodiment.

FIG. 14 is a plan view illustrating a wiring configuration in the display area of the array substrate.

FIG. 15 is a cross-sectional view of the liquid crystal panel taken along line A-A in FIG. 14.

FIG. 16 is a cross-sectional view of the liquid crystal panel taken along line D-D in FIG. 14.

### DETAILED DESCRIPTION

### First Embodiment

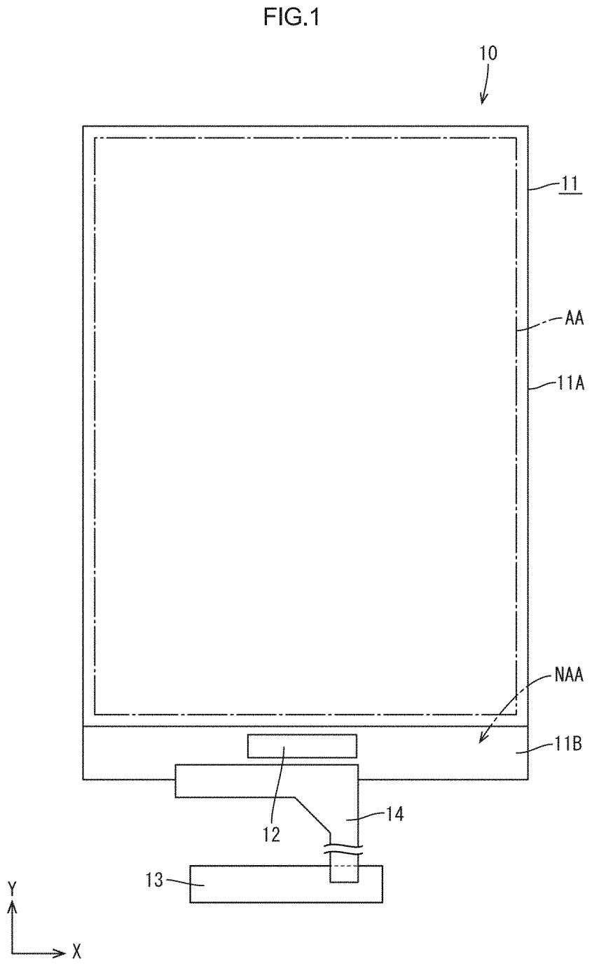

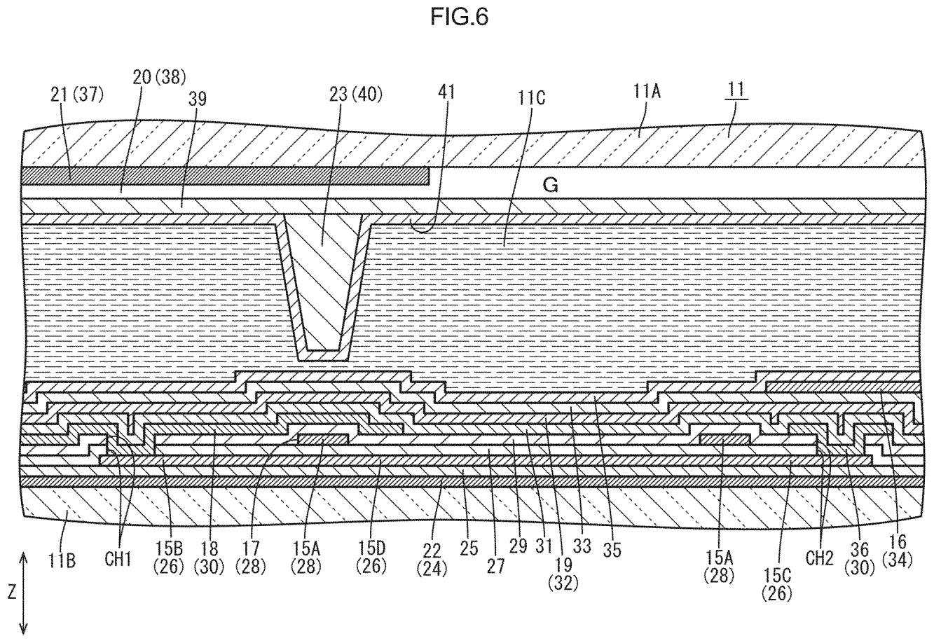

A first embodiment will be described with reference to FIGS. 1 to 9. In the embodiment section, a liquid crystal display device 10 will be described as an example. X-axis, Y-axis and Z-axis may be present in the drawings and each of the axial directions represents a direction represented in each drawing. A vertical direction is defined with reference to FIGS. 6 to 9 and an upper side and a lower side in the drawings correspond to a front side and a back side, respectively.

FIG. 1 is a plan view of a liquid crystal panel 11 included in the liquid crystal display device 10. As illustrated in FIG. 1, the liquid crystal display device 10 includes the liquid crystal panel (a display panel, a display device) 11 displaying images and a backlight device that is disposed on a rear side with respect to the liquid crystal panel 11 and is an external light source supplying light to the liquid crystal panel 11 for displaying. A driver 12 for performing driving for displaying and a flexible circuit board (an external connection component) 14 are mounted on the liquid crystal panel 11 with an anisotropic conductive film (ACF). A control circuit board (an external signal supply source) supplying various kinds of input signals from external devices to the driver 12 is connected to the flexible circuit board 14. The liquid crystal display device 10 of the present embodiment is preferably used in a head-mounted display (HMD) and a screen size thereof is from about several numbers of 0.1 inches to several inches.

As illustrated in FIG. 1, the liquid crystal panel 11 has a display area (an active area) AA in a middle section of a plate surface (a display surface) thereof and a non-display area (a non-active area) NAA on an outer peripheral side of the display area AA. The display area AA displays images. The non-display area NAA has a frame-like plan view shape (or a picture frame-like shape) and does not display an image. An outline of the display area AA is described with a dashed line in FIG. 1 and an area outside the dashed line is the non-display area NAA. The liquid crystal panel 11 at least includes a pair of glass substrates 11A, 11B. One on the front (a front-surface side) is a CF substrate (a first substrate, a counter substrate) 11A and the other one on the rear (a rear-surface side) is an array substrate (a second substrate, a thin film transistor substrate, an active matrix substrate) 11B. Polarizing plates are bonded on outer surfaces of the respective boards 11A and 11B.

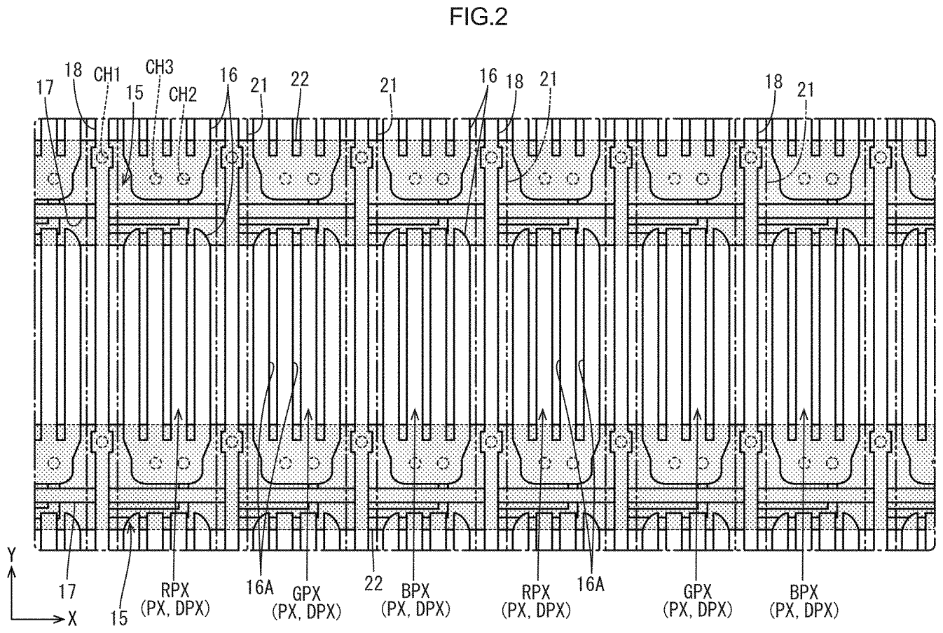

FIG. 2 is a view schematically illustrating pixel arrangement in the display area AA of the array substrate 11B. As illustrated in FIG. 2, on an inner surface side of the display area AA of the array substrate 11B, TFTs (thin film transistors) 15, which are switching components, and pixel electrodes 16 are disposed in a matrix (columns and rows). Gate lines (first lines, scanning lines) 17 and source lines (second lines, signal lines, data lines) 18 are routed in a matrix to surround the TFTs 15 and the pixel electrodes 16. The gate lines 17 extend substantially straight along the X-axis direction (a first direction) and the source lines 18 extend substantially straight along the Y-axis direction (a second direction). A specific structure of the TFT 15 will be described later.

As illustrated in FIG. 2, the pixel electrode 16 is disposed in a substantially vertically-elongated quadrangular area that is surrounded by a pair of gate lines 17 and a pair of source lines 18. The pixel electrode 16 has slits 16A (three slits in FIG. 2) that extend along a long side section thereof. A common electrode 19 is included in a layer lower than the pixel electrode 16 in the array substrate 11B and is formed in a solid manner while overlapping the pixel electrodes 16 (refer FIG. 6). If potential difference is created between the pixel electrode 16 and the common electrode 19 that overlap each other, a horizontal electric filed is primarily created. Namely, in this embodiment, a driving type of the liquid crystal panel 11 is a fringe filed switching (FFS) type.

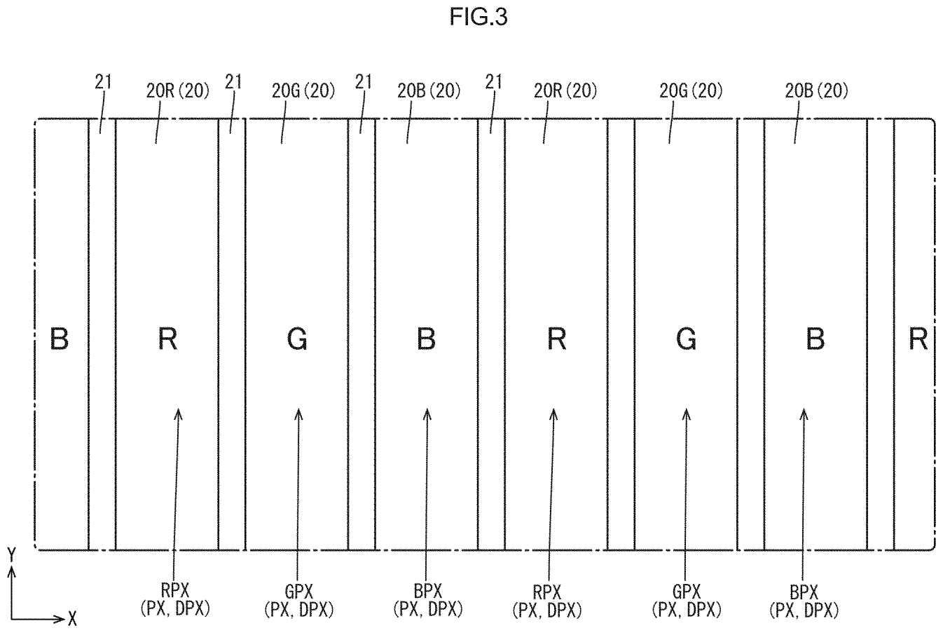

FIG. 3 is a view schematically illustrating pixel arrangement in the display area AA of the CF substrate 11A. As illustrated in FIG. 3, on an inner surface side of the display area AA of the CF substrate 11A, color filters 20 are arranged. The color filters 20 include a red color filter 20R exhibiting red, a blue color filter 20B exhibiting blue, and a green color filter 20G exhibiting green. Red light having a red wavelength range (about 600 nm to about 780 nm) selectively transmits through the red color filter 20R. Blue light having a blue wavelength range (about 420 nm to about 500 nm) selectively transmits through the blue color filter 20B. Green light having a green wavelength range (about 500 nm to about 570 nm) selectively transmits through the green color filter 20G. The red color filter 20R, the green color filter 20G, and the blue color filter 20B form a set of color filters 20 and sets of the color filters 20 are arranged repeatedly in the X-axis direction. The color filter 20R, 20G, 20B of each color extends in the Y-axis direction such that the color filters 20 are arranged in stripes as a whole. The color filters 20 are arranged to overlap the pixel electrodes 16 on the array substrate 11B side in a plan view and a set of the color filter 20 and the pixel electrode 16 configure a pixel PX. The pixels PX are arranged in the X-axis direction and the Y-axis direction within a plane surface area of the liquid crystal panel 11. The pixels PX include a red pixel RPX including the red color filter 20R and exhibiting red, a blue pixel BPX including the blue color filter 20B and exhibiting blue, and a green pixel GPX including the green color filter 20G and exhibiting green. A set of the red pixel RPX, the blue pixel BPX, and the green pixel GPX that are arranged next to each other in the X-axis direction configures a display pixel DPX and the display pixels DPX perform color display according to display gradation of the pixels RPX, BPX, GPX of each color. The liquid crystal panel 11 according to the present embodiment, which is preferably used for a head-mounted display, has a quite high resolution. An arrangement interval between the pixels PX in the X-axis direction is about 8 μm, for example. Line width of each of the gate lines 17 and the source lines 18 is about 1.5 μm, for example.

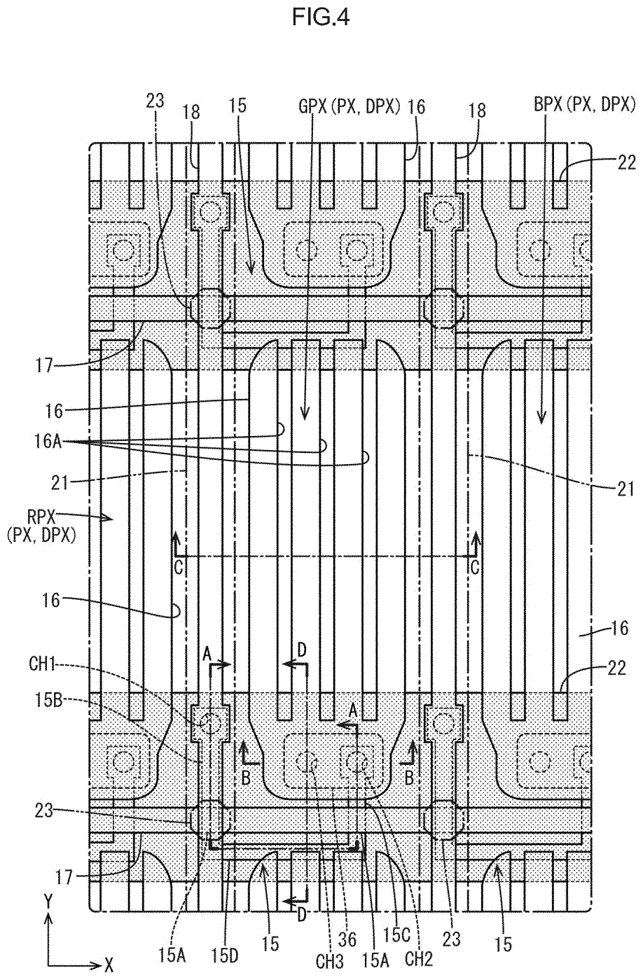

As illustrated in FIGS. 2 and 3, the pixels PX are arranged in a matrix in the X-axis direction and the Y-axis direction and the pixels PX adjacent to each other are divided by a first light blocking section 21 and a second light blocking section 22 such that light is less likely to travel between them. In FIGS. 2 and 4, the first light blocking sections 21 are illustrated with two-dot chain lines and the second light blocking sections 22 are illustrated with shading. In the present embodiment, the first light blocking sections 21 are provided on the CF substrate 11A side and the second light blocking sections 22 are provided on the array substrate 11B side. Specifically, as illustrated in FIG. 3, the first light blocking sections 21 extend in the Y-axis direction and are arranged to define each of the pixels PX that are adjacent to each other in the X-axis direction. The first light blocking sections 21 are arranged in the X-axis direction at intervals each corresponding to a short-side dimension of the pixel PX (arrangement pitch of the pixels PX in the X-axis direction). The first light blocking section 21 overlaps the source line 18 on the array substrate 11B side and has a width dimension that is greater than a width dimension of the source line 18. As illustrated in FIG. 2, the second light blocking section 22 extends in the X-axis direction and is arranged to define each of the pixel electrodes PX that are adjacent to each other in the Y-axis direction. Thus, the second light blocking sections 22 are arranged at intervals each corresponding to a long side dimension of the pixel PX in the Y-axis direction (an arrangement pitch of the pixel electrode PX in the Y-axis direction). The second light blocking section 22 is disposed to overlap the gate line 17 and a width dimension thereof is greater than a width dimension of the gate line 17.

Here, the first light blocking section and the second light blocking section have been generally provided on only the CF substrate 11A side. In such a structure, if the pixel PX is reduced in size in response to higher resolution, following problems may be caused. Namely, if the photolithography method is used such that a film of photosensitive material is exposed to light and developed through a photomask to form the first light blocking section and the second light blocking section with patterning, a following problem may be caused. If the size of the pixel PX is reduced too small to deal with the lowest resolution limit for the light exposure, it becomes difficult to control the area of forming holes in the first light blocking section and the second light blocking section and the aperture ratio of the pixel PX may be extremely lowered. More specifically, the hole in the first light blocking section and the second light blocking section has a shape having chamfered four corners corresponding to the quadrangular pixel electrode 16 and this may lower the aperture ratio of the pixel PX. In forming the first light blocking section and the second light blocking section with a printing method also, the aperture ratio of the pixel PX may be extremely lowered. In this respect, the first light blocking section 21 that extends in the Y-axis direction and between the pixels PX that are adjacent to each other in the X-axis direction is included in the CF substrate 11A and the second light blocking section 22 that extends in the X-axis direction and between the pixels PX that are adjacent to each other in the Y-axis direction is included in the array substrate 11B. According to such a configuration, even if the size of the pixel PX is further reduced according to the higher resolution, the aperture area of the pixel PX can be appropriately controlled regardless of the method of forming the first light blocking section 21 and the second light blocking section 22. Accordingly, the aperture ratio of the pixel PX is less likely to be lowered. Light may be scattered at two edges of the gate line 17 disposed on the array substrate 11B. However, the second light blocking section 22 is disposed to overlap the gate line 17 such that scattered light is blocked by the second light blocking section 22 even if scattered light is created at the edges of the gate line 17. Thus, lowering of the contrast properties is less likely to be caused. Light may be scattered at two edges of the source line 18 disposed on the array substrate 11B. However, the first light blocking section 21 is disposed to overlap the source line 18 such that scattered light is blocked by the first light blocking section 21 even if scattered light is created at the edges of the source line 18. Thus, lowering of the contrast properties is less likely to be caused. Furthermore, the line width of the gate line 17 and the source line 18 can be designed more freely and the light blocking region of the first light blocking section and the second light blocking section can be designed more freely.

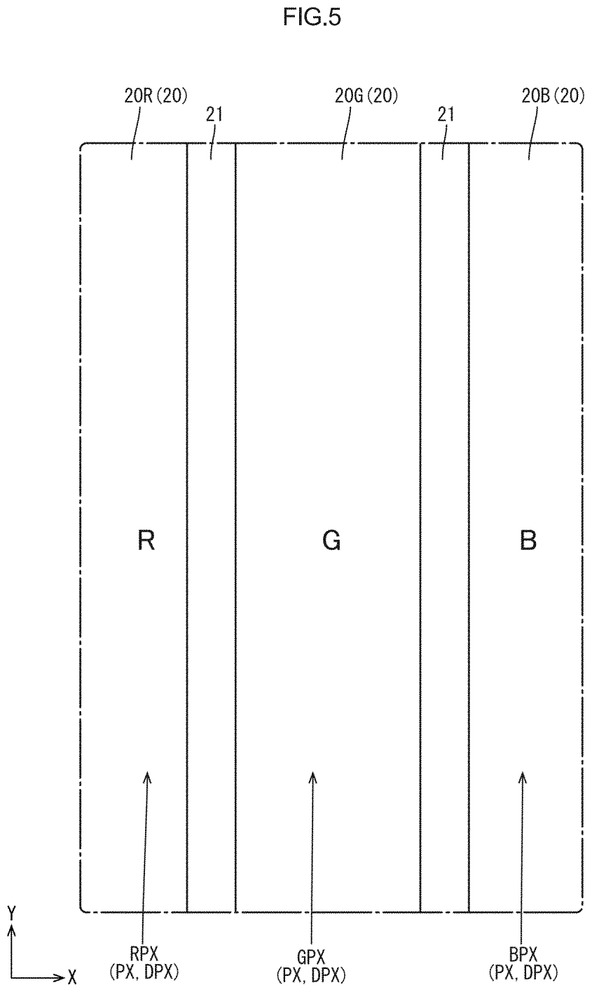

A configuration of the TFT 15 will be described with reference to FIG. 4. FIG. 4 is a plan view illustrating a wiring structure in the display area AA of the array substrate 11B. As illustrated in FIG. 4, the TFT 15 includes a gate electrode 15A connected to the gate line 17, a source region 15B connected to the source line 18, a drain region 15C connected to the pixel electrode 16, and a channel region 15D connected to the source region 15B and the drain region 15C. The TFT 15 is driven based on the scanning signal supplied through the gate line 17. Then, the potential relating the image signal that is supplied to the source line 18 is supplied to the drain region 15C through the channel region 15D such that the pixel electrode 16 is charged at the potential relating the image signal. The gate electrode 15A is a section of the gate line 17 that overlaps the channel region 15D, which will be described later. The source region 15B extends in the Y-axis direction and entirely overlaps the source line 18. The drain region 15C extends in the Y-axis direction and most part thereof overlaps the pixel electrode 16. The drain region 15C is connected to the pixel electrode 16 through a connection electrode 36, as will be described later. The channel region 15D is a plan-view channel-type and one end thereof is continuous to the source region 15B and another end thereof is continuous to the drain region 15C. The channel region 15D includes a pair of sections extending in the Y-axis direction and the pair of sections overlap the gate lines 17. The pair of overlapping sections overlapping the gate lines 17 are continuous to the source region 15B and the drain region 15C, respectively. The channel region 15D includes a section extending in the X-axis direction and the section is disposed on an opposite side from the pixel electrode 16, which is a target to be connected, with respect to the Y-axis direction while having the gate line 17 therebetween. Spacers 23 included in the CF substrate 11A are to be contacted with sections of the array substrate 11B where the gate lines 17 and the source lines 18 crosses. The spacers 23 will be described later. The three pixels PX arrayed in the X-axis direction in FIG. 4 include the red pixel RPX, the green pixel GPX, and the blue pixel BPX in this sequence from the left side in the drawing. A plan view of the display area AA of the CF substrate 11A that is arranged opposite the array substrate 11B illustrated in FIG. 4 is illustrated in FIG. 5.

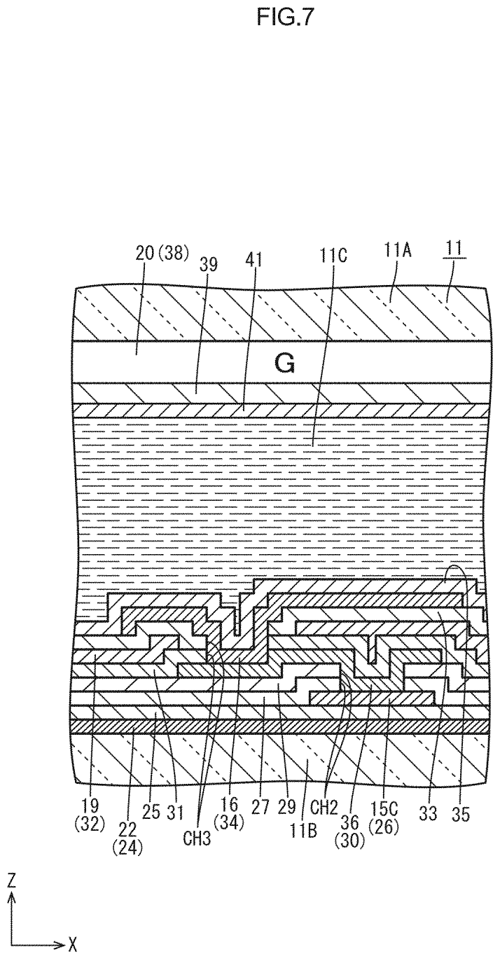

Next, a specific stacking order of various kinds of films stacked on an inner surface side of the CF substrate 11A and the array substrate 11B with the known photolithography method will be described in detail with reference to FIGS. 6 and 7. FIG. 6 is a cross-sectional view of the TFT 15. FIG. 7 is a cross-sectional view of the connection electrode 36. A liquid crystal layer 11C is sandwiched between the substrates 11A and 11B. First, a stacking structure of the array substrate 11B will be described. As illustrated in FIG. 6, on the array substrate 11B, the films are at least stacked in the following sequence from the lowest layer: a first metal film (a light blocking film) 24, a first insulation film (a base coat film) 25, a semiconductor film 26, a second insulation film 27, a second metal film (a gate metal film) 28, a third insulation film 29, a third metal film (a source metal film) 30, a fourth insulation film 31, a first transparent electrode film 32, a fifth insulation film 33, a second transparent electrode film 34, and an array-side alignment film 35.

Each of the first metal film 24, the second metal film 28, and the third metal film 30 is a single layer film made of one kind of metal material or a multilayer film made of different kinds of metal materials or an alloy to have conductivity and light blocking properties. As illustrated in FIG. 6, the second light blocking section 22 is a portion of the first metal film 24. The gate line 17 and the gate electrode 15A of the TFT 15 are portions of the second metal film 28. The source line 18 and the connection electrode 36 are portions of the third metal film 30. Each of the first insulation film 25, the second insulation film 27, the third insulation film 29, the fourth insulation film 31, and the fifth insulation film 33 is made of silicon oxide (SiO₂) or silicon nitride (SiNₓ) that is one kind of inorganic insulation material (inorganic resin material). Contact holes CH1, CH2 are formed respectively in sections of the second insulation film 27 and the third insulation film 29 overlapping the source line 18 and the source region 15B and in sections thereof overlapping the drain region 15C and the connection electrode 36 for connecting the overlapping sections with one another. As illustrated in FIG. 7, a contact hole CH3 is formed in sections of the fourth insulation film 31 and the fifth insulation film 33 overlapping the connection electrode 36 and the pixel electrode 16 for connecting the overlapping sections with one another.

The semiconductor film 26 is made of a continuous grain (CG) silicon thin film that is a kind of a polycrystallized silicon film (a polycrystalline silicone film). The CG silicon film is formed as follows. Metal material is added to an amorphous silicon thin film and the additive is subjected to a heating process at a low temperature of 550° C. or lower for a short time. Accordingly, atomic arrangement at a crystal grain boundary of the silicon crystals has continuity. As illustrated in FIG. 6, the semiconductor film 26 is formed with patterning in an island form in the display area AA according to the arrangement of the TFTs 15. The semiconductor film 26 forms the source region 15B, the drain region 15C, and the channel region 15D of the first TFT 15. The first transparent electrode film 32 and the second transparent electrode film 34 are made of transparent electrode material such as indium tin oxide (ITO) or indium zinc oxide (IZO). The first transparent electrode film 32 forms the common electrode 19 and the second transparent electrode film 34 forms the pixel electrodes 16. The array-side alignment film 35 is made of alignment material such as polyimide and a surface thereof is subjected to a rubbing treatment or an optical alignment treatment.

Next, a stacking structure of the CF substrate 11A will be described. As illustrated in FIG. 6, on the CF substrate 11A, the films are at least stacked in the following sequence from the lowest layer: a light blocking film (a light blocking resist film) 37, a color resist film 38, an overcoat film 39, a photoresist film 40, and a CF-side alignment film 41. The light blocking film 37 is made of light blocking material (such as carbon black) having photosensitivity and exhibiting black and a portion thereof is the first light blocking section 21. The color resist film 38 is made of coloring material having photosensitivity and portions thereof are the color filters 20 of respective colors. The overcoat film 39 is made of organic insulation material (organic resin material) and has a function of planarizing a surface of the CF substrate 11A. The photoresist film 40 is made of organic insulation material (organic resin material) having photosensitivity and portions thereof are the spacers 23. The spacer 23 projects through the liquid crystal layer 11C and a projected end thereof is contacted with an inner surface of the array substrate 11B to keep a thickness (a cell gap) of the liquid crystal layer 11C to be constant. The CF-side alignment film 41 is made of the alignment film such as polyimide and a surface thereof is subjected to a rubbing treatment or an optical alignment treatment similar to the array-side alignment film 35.

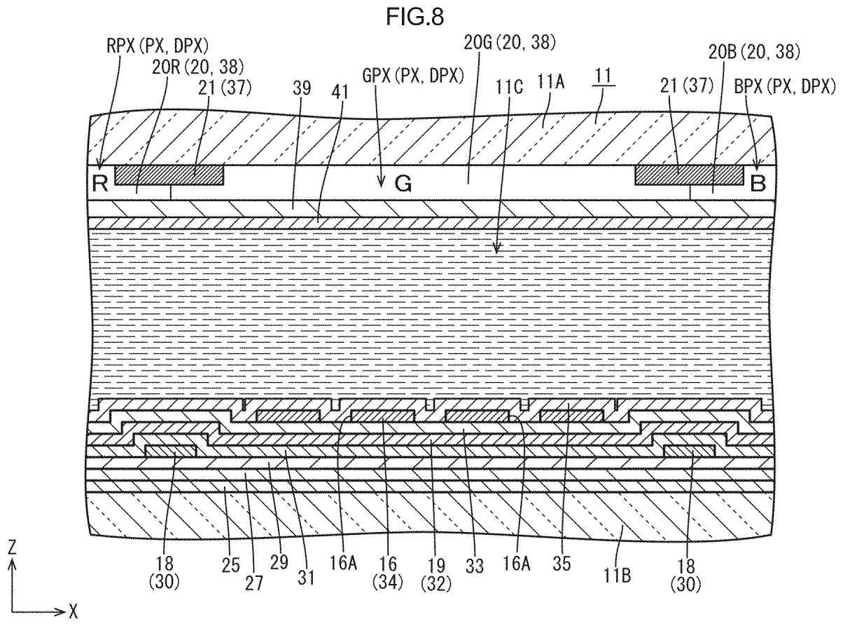

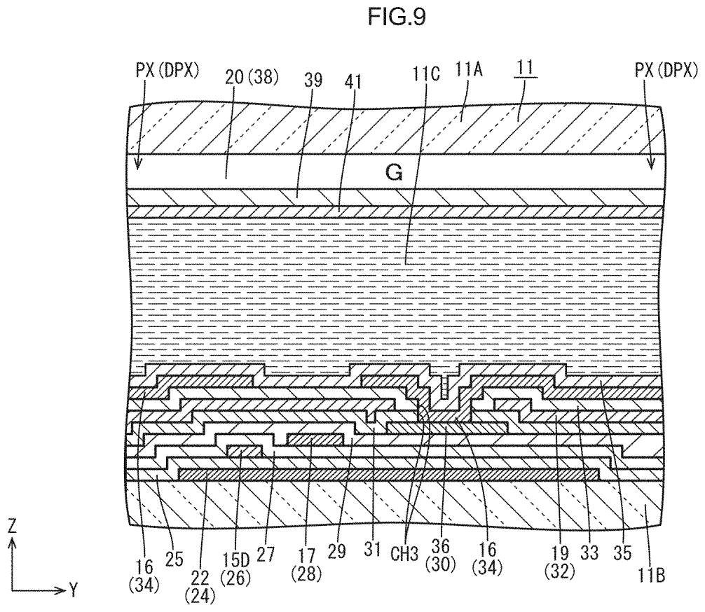

Next, detailed configurations of the first light blocking section 21 and the second light blocking section 22 will be described with reference to FIGS. 8 and 9. FIG. 8 is a cross-sectional view of the first light blocking section 21. FIG. 9 is a cross-sectional view of the second light blocking section 22. As illustrated in FIGS. 4 and 8, the first light blocking section 21 is disposed such that a middle position thereof with respect to the X-axis direction matches a middle position of the source line 18 and a width dimension thereof is greater than the line width of the source line 18. The first light blocking section 21 has a non-separated structure and extends in the Y-axis direction and parallel to the source line 18 and overlaps the source line 18 over an entire length and an entire width of the source line 18.

As illustrated in FIGS. 4 and 9, the second light blocking section 22 is disposed such that a middle position thereof with respect to the Y-axis direction matches a middle position of the gate line 17 and a width dimension thereof is greater than the line width of the gate line 17. The second light blocking section 22 has a non-separated structure and extends in the X-axis direction and parallel to the gate line 17 and overlaps the gate line 17 over an entire length and an entire width of the gate line 17 continuously. According to such a structure, the light leaking due to the gate line 17 is prevented by the second light blocking section 22 with high reliability and the lowering of the contrast properties is restricted more appropriately. Thus, the second light blocking section 22 covers a substantially entire area of the gate line 17 and therefore, the second light blocking section also covers the spacers 23 that are disposed at intersections of the gate lines 17 and the source lines 18. Near the spacers 23, the light may be refracted by the spacers 23 and the light leaking may be caused. However, the second light blocking section 22 is disposed to overlap the spacers 23 and therefore, the leaking light that may be possibly caused near the spacers 23 is blocked by the second light blocking section 22. Accordingly, the lowering of the contrast properties is restricted more appropriately.

Furthermore, as illustrated in FIGS. 4 and 9, the second light blocking section 22 overlaps an entire area of each TFT 15, a part of each pixel electrode 16, and an entire area of each spacer 23 in addition to the gate line 17. More in detail, the second light blocking section 22 overlaps all of the gate electrode 15A, the source region 15B, the drain region 15C, and the channel region 15D of the TFT 15. The second light blocking section 22 is a portion of the first metal film 24 that is included on a lower layer side of the semiconductor film 26 a portion of which is the channel region 15D while having the first insulation film 25 therebetween. Therefore, the second light blocking section 22 blocks light that is supplied to the channel region 15D from the lower layer side, for example, from the backlight device. Accordingly, unnecessary electron movement is less likely to be caused by the supply of light in the channel region 15D and therefore, operation errors are less likely to occur in the TFT 15. The second light blocking section 22 also overlaps the contact holes CH1 through which the source region 15B is connected to the source line 18 and the contact holes CH2 (connecting section) through which the drain region 15C is connected to the connection electrode 36. Therefore, the second light blocking section 22 blocks leaking light that may be caused by unevenness formed on the surface of the array substrate 11B due to the contact holes CH1, CH2. Accordingly, the lowering of the contrast properties is restricted more appropriately. The second light blocking section 22 overlaps an entire area of the connection electrode 36 that is connected to the drain region 15C. Therefore, the second light blocking section 22 also overlaps the contact holes CH3 (connecting section) through which the connection electrode 36 is connected to the pixel electrode 16. Therefore, the second light blocking section 22 blocks leaking light that may be caused by unevenness formed on the surface of the array substrate 11B due to the contact holes CH3. Accordingly, the lowering of the contrast properties is restricted more appropriately.

As described before, the liquid crystal panel (the display device) 11 according to the present embodiment includes the CF substrate (a first substrate) 11A, the array substrate (a second substrate) 11B arranged opposite the CF substrate 11A, the pixels PX arranged in a matrix within plate surface areas of CF substrate 11A and the array substrate 11B, the gate lines (first line) 17 disposed on the array substrate 11B and extending in a first direction, the first light blocking section 21, and the second light blocking section 22. The first light blocking section 21 is disposed on the CF substrate 11A and extends along the plate surface of the CF substrate 11A and extends in a second direction crossing the first direction and is between the pixels PX that are adjacent to each other in the first direction. The second light blocking section 22 is disposed on the array substrate 11B and extends in the first direction and is between the pixels PX that are adjacent to each other in the second direction and overlaps the gate line 17.

The first light blocking section 21 is between the pixels PX that are adjacent to each other in the first direction and the second light blocking section 22 is between the pixels PX that are adjacent to each other in the second direction. According to such a configuration, the light is less likely to cross over the pixels PX that area adjacent to each other in the first direction and the second direction. Compared to a previous configuration that the coloring layers exhibiting different colors are stacked on to block light, the first light blocking section 21 and the second light blocking section 22 can obtain sufficient light blocking properties. Accordingly, the lowering of the contrast properties is restricted more appropriately.

If the first light blocking section and the second light blocking section are included only on the CF substrate 11A side and the pixel PX is reduced in size according to the higher resolution, following problems may be caused. Namely, if the photolithography method is used such that a film of photosensitive material is exposed to light and developed through a photomask to form the first light blocking section and the second light blocking section with patterning, a following problem may be caused. If the size of the pixel PX is reduced too small to deal with the lowest resolution limit for the light exposure, it becomes difficult to control the area of forming holes in the first light blocking section and the second light blocking section and the aperture ratio of the pixel PX may be extremely lowered. Also in forming the first light blocking section and the second light blocking section with a printing method, the aperture ratio of the pixel PX may be extremely lowered. In this respect, the first light blocking section 21 that extends in the second direction and between the pixels PX that are adjacent to each other in the first direction is provided on the CF substrate 11A and the second light blocking section 22 that extends in the first direction and between the pixels PX that are adjacent to each other in the second direction is provided on the array substrate 11B. According to such a configuration, even if the size of the pixel PX is reduced smaller according to the higher resolution, the aperture area of the pixel PX can be appropriately controlled regardless of the method of forming the first light blocking section 21 and the second light blocking section 22. Accordingly, the aperture ratio of the pixel PX is less likely to be greatly lowered. Light may be scattered at two edges of the gate line 17 disposed on the array substrate 11B. However, the second light blocking section 22 is disposed to overlap the gate line 17 such that scattered light is blocked by the second light blocking section 22 even if scattered light is created at the edges of the gate line 17. Thus, lowering of the contrast properties is less likely to be caused. Furthermore, the line width of the gate line 17 and the source line 18 can be designed more freely and the light blocking region of the second light blocking section can be designed more freely.

The source lines (the second line) 18 are disposed on the array substrate 11B and extend in the second direction and the first light blocking section 21 overlaps the source line 18. Light may be scattered at two edges of the source line 18 disposed on the array substrate 11B. However, the first light blocking section 21 is disposed to overlap the source line 18 such that scattered light is blocked by the first light blocking section 21 even if scattered light is created at the edges of the source line 18. Thus, lowering of the contrast properties is preferably restricted. Furthermore, the line width of the source line 18 can be designed more freely and the light blocking region of the first light blocking section 21 can be designed more freely.

The TFT (thin film transistor) 15 that is connected to the gate line 17 and the source line 18 is disposed on the array substrate 11B and the second light blocking section 22 is disposed to overlap at least a part of the TFT 15. Unevenness caused by the TFTs 15 is likely to be created on a surface of the array substrate 11B at sections where the TFTs 15 are provided and light leaking may be caused due to the unevenness. In this respect, the second light blocking section 22 that can be freely designed to have a desired light blocking area is disposed to overlap at least a part of the TFT 15. Accordingly, the light leaking possibly caused near the TFT 15 is restricted and lowering of the contrast properties is preferably restricted.

The TFT 15 includes the gate electrode 15A connected to the gate line 17, the source region 15B connected to the source line 18, the channel region 15D, and the drain region 15C. The channel region 15D is disposed on a lower layer side of the gate electrode 15A while having the second insulation film (an insulation film) 27 therebetween and overlapping at least a part of the gate electrode 15A and is connected to the source region 15B. The drain region 15C is connected to the channel region 15D at an opposite side from the source region 15B side. The second light blocking section 22 is disposed to overlap at least the channel region 15D of the TFT 15 on a lower layer side thereof. According to such a configuration, if the gate electrode 15A is supplied with power by the signal transmitted through the gate line 17, the TFT 15 is driven and the signal transmitted through the source line 18 is supplied from the source region 15B to the drain region 15C through the channel region 15D. The channel region 15D is disposed such that at least a part thereof overlaps the gate electrode 15A via the second insulation film 27 on the lower layer side of the gate electrode 15A. Therefore, if the light is supplied to the channel region 15D from the lower layer side, unnecessary electron movement may occur in the channel region 15D. In this respect, the second light blocking section 22 is disposed to overlap the channel region 15D on the lower layer side of the channel region 15D and therefore, the second light blocking section 22 blocks the light supplied to the channel region 15D from the lower layer side thereof. Thus, unnecessary electron movement is less likely to occur in the channel region 15D and operation errors are less likely to be caused in the TFT 15.

The pixel PX includes the color filter 20 included in the CF substrate 11A and the pixel electrode 16 included in the array substrate 11B while overlapping the color filter 20 and connected to the TFT 15. The second light blocking section 22 is disposed to overlap the connection section (the contact holes CH2, CH3) between the TFT 15 and the pixel electrode 16. Unevenness due to the connection section is likely to be created on a surface of the array substrate 11B at the connection section between the TFT 15 and the pixel electrode 16 and light leaking may be caused due to the unevenness. In this respect, the second light blocking section 22 that can be freely designed to have a desired light blocking area is disposed to overlap the connection section. Accordingly, the light leaking possibly caused near the connection section is restricted and lowering of the contrast properties is preferably restricted.

The spacer 23 is included between the CF substrate 11A and the array substrate 11B and keeps the space therebetween and the second light blocking section 22 is disposed to overlap the spacers 23. Near the spacers 23 that are between the CF substrate 11A and the array substrate 11B, the light may be refracted by the spacers 23 and the light leaking may be caused. In this respect, the second light blocking section 22 that can be freely designed to have a desired light blocking area is disposed to overlap the spacers 23. Accordingly, the light leaking possibly caused near the spacers 23 is restricted and lowering of the contrast properties is preferably restricted.

The second light blocking section 22 is formed in a non-separated structure and extends in the first direction and parallel to the gate line 17. According to such a structure, the second light blocking section 22 covers the gate line 17 continuously in the first direction. According to such a structure, the light leaking due to the gate line 17 is prevented by the second light blocking section 22 with high reliability and the lowering of the contrast properties is restricted more appropriately.

### Second Embodiment

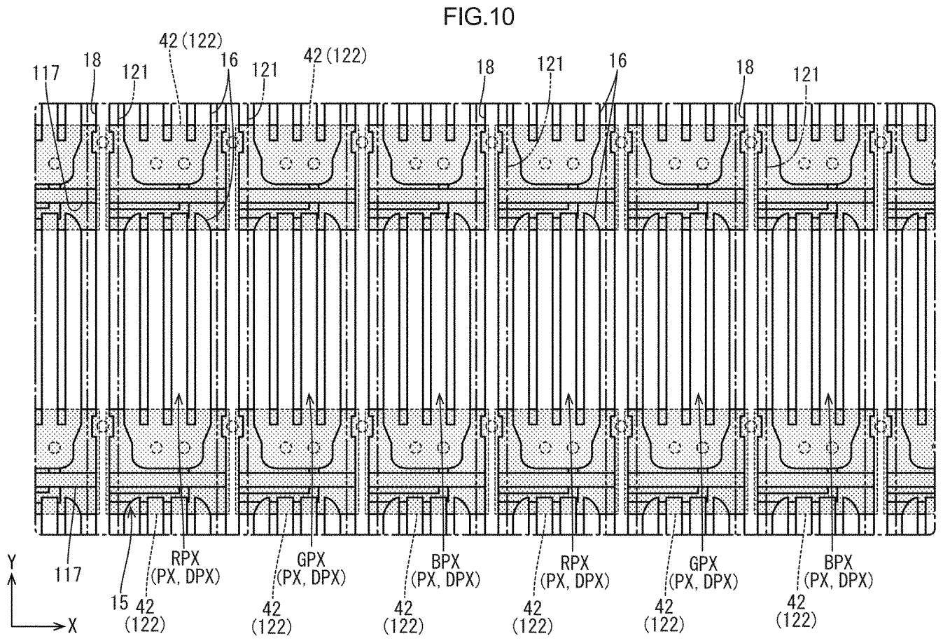

A second embodiment will be described with reference to FIG. 10. In the second embodiment, a structure of a second light blocking section 122 is altered. Configurations, operations, and effects similar to those of the first embodiment will not be described.

As illustrated in FIG. 10, the second light blocking section 122 has a separated structure. In detail, the second light blocking section 122 includes separated second light blocking sections 42 that are arranged in the X-axis direction, which is an extending direction of a gate line 117. The separated second light blocking section 42 has a length dimension in the X-axis direction that substantially matches an arrangement pitch of the pixels PX that are arranged in the X-axis direction. The second light blocking section 122 is disposed such that a position (a separation position) between the separated second light blocking sections 42 that are adjacent to each other in the X-axis direction matches a position between the pixels PX that are adjacent to each other in the X-axis direction. The number of separation of the second light blocking section 122, that is, the number of the separated second light blocking sections 42 included in the second light blocking section 122 is same as the number of the pixels PX arranged in the X-axis direction. Accordingly, even if a signal is unintentionally input to one of the separated second light blocking sections 42 from an external device, the signal is not transferred from the one separated second light blocking section 42 to another separated second light blocking section 42 next thereto. Specifically, the second light blocking section 122 is separated into the separated second light blocking sections 42 so as to correspond to the respective pixels PX that are arranged in the X-axis direction. Therefore, even if a signal is unintentionally input to one of the separated second light blocking sections 42 from an external device, the pixel PX receives only least adverse influence that may be possibly caused by the signal. Therefore, the gate line 117 overlapping the second light blocking section 122 is less likely to be adversely affected by noise, for example. The second light blocking section 122 overlaps a first light blocking section 121 at sections thereof between the separated second light blocking sections 42 that are adjacent in the X-axis direction. Therefore, light that may possibly leak through sections between the adjacent separated second light blocking sections 42 is blocked by the first light blocking section 121. Accordingly, the lowering of the contrast properties is restricted more appropriately.

According to the present embodiment, as described before, the second light blocking section 122 includes the separated second light blocking sections 42 that are arranged in the first direction. Accordingly, even if a signal is unintentionally input to one of the separated second light blocking sections 42 from an external device, the signal is not transmit to the separated second light blocking section 42 that is next to the one separated second light blocking section 42. Therefore, the gate line 117 overlapping the second light blocking section 122 is less likely to receive adverse influence such as noise, for example.

The second light blocking section 122 is provided such that a length of the separated second light blocking section 42 in the first direction matches the arrangement pitch of the pixels PX in the first direction. Accordingly, the second light blocking section 122 is separated into the separated second light blocking sections 42 so as to correspond to the respective pixels PX. Therefore, even if a signal is unintentionally input to one of the separated second light blocking sections 42 from an external device, the pixel PX receives only least adverse influence that may be possibly caused by the signal.

Furthermore, the second light blocking section 122 has the separation position between the separated second light blocking sections 42 so as to overlap the first light blocking section 121. According to such a configuration, the light that may possibly leak through the sections between the adjacent separated second light blocking sections 42 can be blocked by the first light blocking section 121. Accordingly, the lowering of the contrast properties is restricted more appropriately.

### Third Embodiment

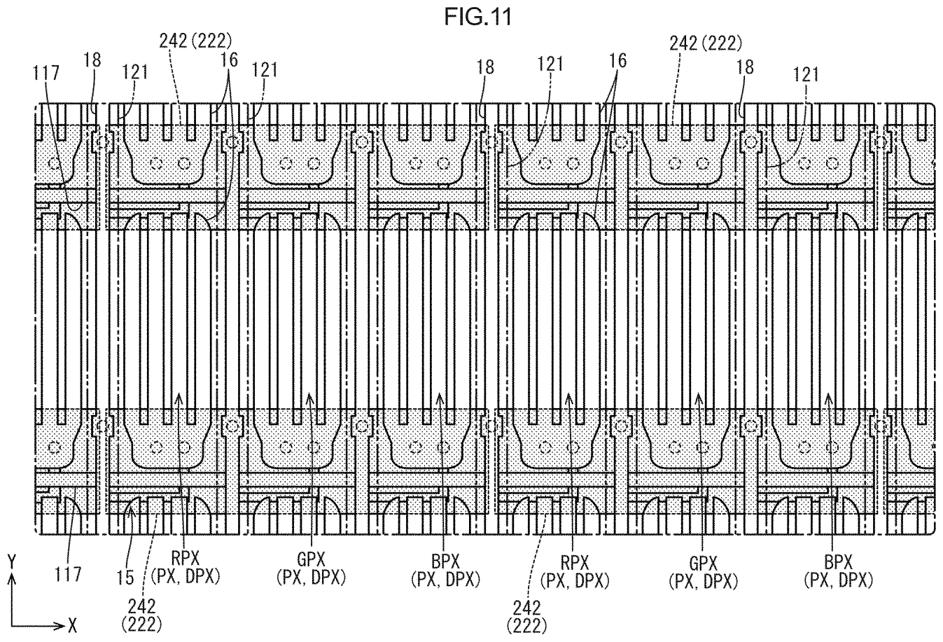

A third embodiment will be described with reference to FIG. 11. In the third embodiment, a structure of a second light blocking section 222 is altered from the second embodiment. Configurations, operations, and effects similar to those of the second embodiment will not be described.

As illustrated in FIG. 11, the second light blocking section 222 according to the present embodiment includes separated second light blocking sections 242 and the separated second light blocking section 242 has a length in the X-axis direction that matches an integral multiple of the arrangement pitch of display pixels DPX. Specifically, in the present embodiment, the length of the separated second light blocking section 242 in the X-axis direction is one time of the arrangement pitch of the display pixels DPX in the X-axis direction. Namely, the separated second light blocking section 242 has a forming area ranging over the three pixels PX of the red pixel RPX, the green pixel GPX, and the blue pixel BPX that are arranged continuously in the X-axis direction. The separation number of the second light blocking section 222 is about one-third of the number of the pixels PX arranged in the X-axis direction. According to such a configuration, even if a signal is unintentionally input to one of the separated second light blocking sections 242 from an external device, the display pixel DPX is less likely to receive adverse influence that may be possibly caused by the signal.

According to the present embodiment, as described before, the pixels PX include the red pixels RPX exhibiting red, the green pixels GPX exhibiting green, and the blue pixels BPX exhibiting blue. One display pixel DPX includes the red pixel RPX, the green pixel GPX, and the blue pixel BPX that are continuously arranged in the first direction. The second light blocking section 222 is provided such that a length of the separated second light blocking section 242 in the first direction matches an integral multiple of the arrangement pitch of display pixels DPX in the first direction. According to such a configuration, the red pixel RPX, the green pixel GPX, and the blue pixel BPX that are arranged continuously in the first direction are displayed with a predetermined gradation respectively such that color display is performed with one display pixel DPX. The second light blocking section 222 is separated into the separated second light blocking sections 242 each corresponding to every display pixel DPX or multiple display pixels DPX. According to such a configuration, even if a signal is unintentionally input to one of the separated second light blocking sections 242 from an external device, the display pixel DPX is less likely to receive adverse influence that may be possibly caused by the signal.

The second light blocking section 222 is provided such that a length of the separated second light blocking section 242 in the first direction matches the arrangement pitch of display pixels DPX in the first direction. According to such a configuration, the second light blocking section 222 is separated into the separated second light blocking sections 242 each corresponding to every display pixel DPX. Therefore, even if a signal is unintentionally input to one of the separated second light blocking sections 242 from an external device, the display pixel DPX is less likely to receive adverse influence that may be possibly caused by the signal.

### Fourth Embodiment

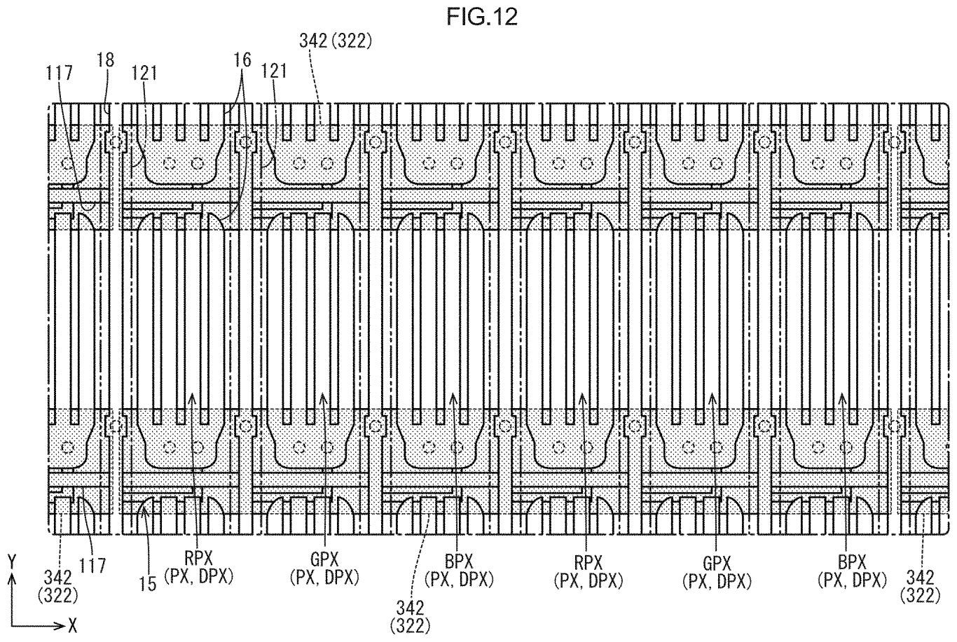

A fourth embodiment will be described with reference to FIG. 12. In the fourth embodiment, a structure of a second light blocking section 322 is altered from the third embodiment. Configurations, operations, and effects similar to those of the third embodiment will not be described.

As illustrated in FIG. 12, the second light blocking section 322 according to the present embodiment includes separated second light blocking sections 342 and a length of the separated second light blocking section 342 in the X-axis direction matches two times of the arrangement pitch of the display pixels DPX in the X-axis direction. Namely, the separated second light blocking section 342 has a forming area ranging over the two display pixels DPX, that is, ranging over the six pixels PX of the red pixels RPX, the green pixels GPX, and the blue pixels BPX that are arranged continuously in the X-axis direction. The separation number of the second light blocking section 322 is about one-sixth of the number of the pixels PX arranged in the X-axis direction. Thus, the second light blocking section 322 is separated into the separated second light blocking sections 342 each corresponding to every two display pixels DPX. According to such a configuration, even if a signal is unintentionally input to one of the separated second light blocking sections 342 from an external device, the display pixel DPX is less likely to receive adverse influence that may be possibly caused by the signal.

### Fifth Embodiment

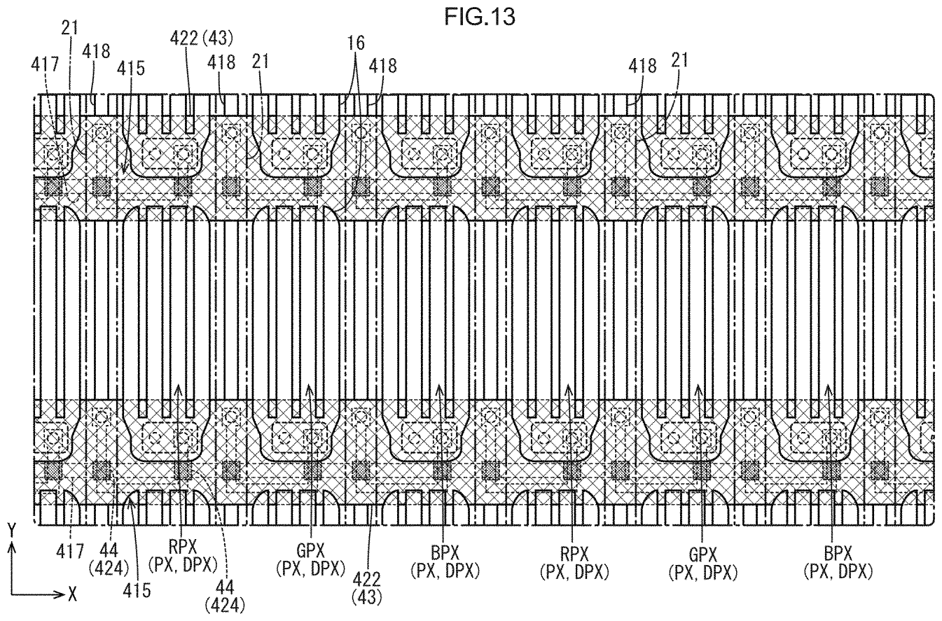

A fifth embodiment will be described with reference to FIGS. 13 to 16. In the fifth embodiment, a structure of a second light blocking section 422 is altered from the first embodiment. Configurations, operations, and effects similar to those of the first embodiment will not be described.

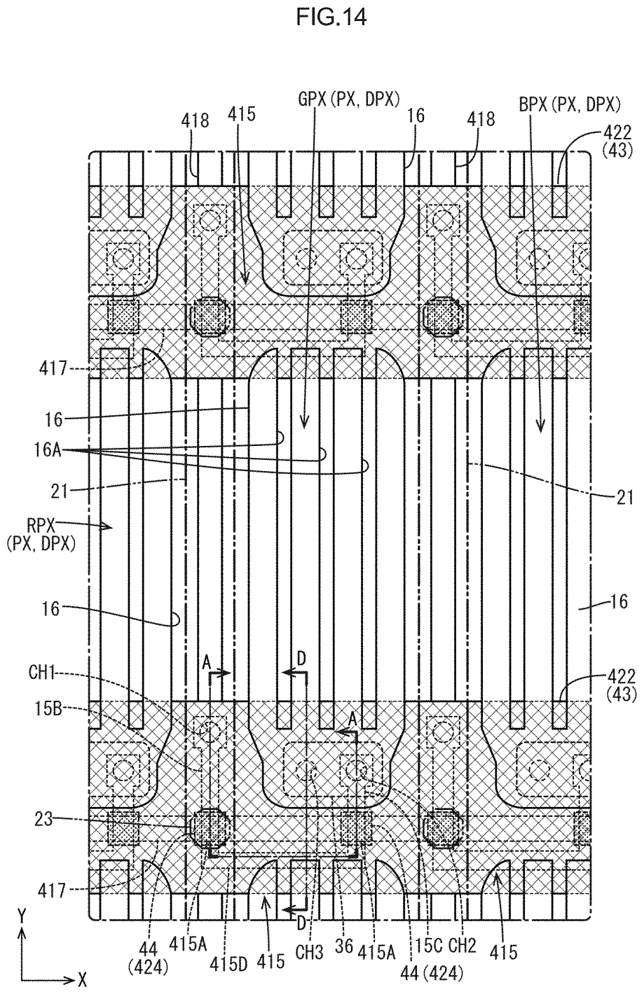

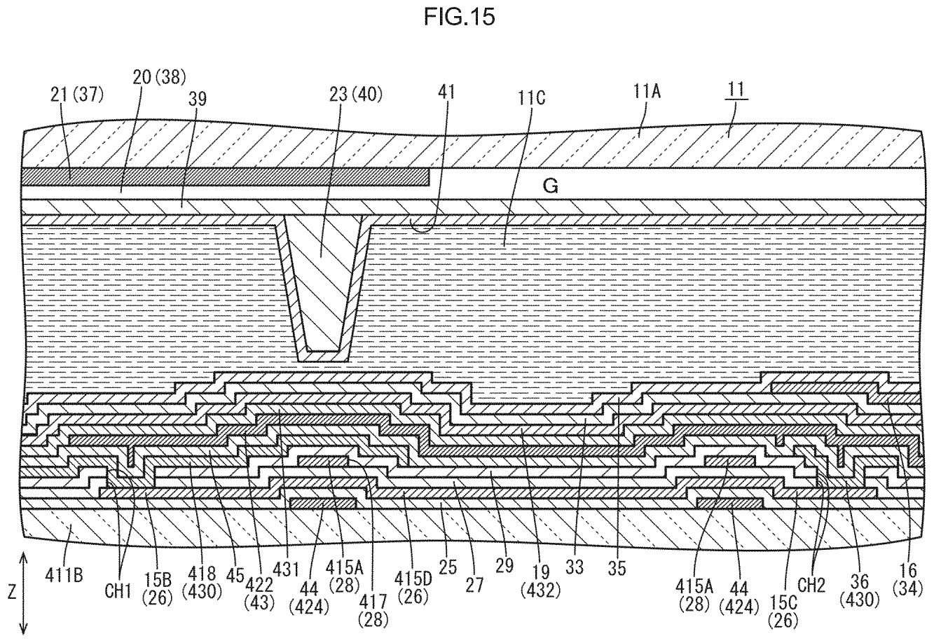

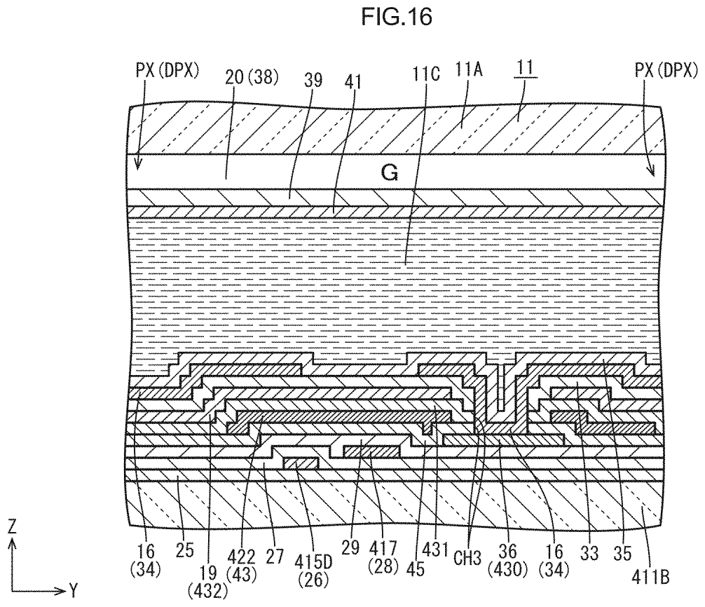

As illustrated in FIGS. 13 and 14, an array substrate 411B according to the present embodiment includes a fourth metal film 43 disposed on an upper layer side of a third metal film 430 portions of which are source lines 418. A portion of the fourth metal film 43 is the second light blocking section 422. A portion of a first metal film 424 is a third light blocking section 44 that overlaps a part of a channel region 415D of a TFT 415. The second light blocking section 422 and the third light blocking section 44 are illustrated with different shadings in FIGS. 13 and 14. In detail, as illustrated in FIGS. 15 and 16, the fourth metal film 43 a portion thereof is the second light blocking section 422 is disposed on an upper layer side of a sixth insulation film 45 that is disposed on an upper layer side of the third metal film 430. Therefore, the fourth metal film 43 is insulated from the third metal film 430 by the sixth insulation film 45 on an lower layer side thereof and is insulated from a first transparent electrode film 432 by a fourth insulation film 431 on an upper layer side thereof. A configuration of the second light blocking section 422 is as described in the first embodiment section except for the feature that the second light blocking section 422 is a portion of the fourth metal film 43.

As illustrated in FIGS. 14 and 15, the third light blocking section 44 is formed to selectively overlap a pair of overlapping sections of the channel region 415D of the TFT 415 that overlap the gate lines 417 (gate electrodes 315A). If the gate electrode 415A has a potential corresponding to a scanning signal transmitted to the gate line 417, the electron mobility is accelerated in the pair of overlapping sections of the channel region 415D overlapping the gate electrodes 415A. If light is supplied to the pair of overlapping sections of the channel region 415D from the lower layer side and this causes unintentional electron movement, operations of the TFT 415 are particularly likely to be adversely affected. In this respect, the third light blocking section 44 that is a portion of the first metal film 424 selectively overlaps the pair of overlapping sections of the channel region 415D so as to block the light that may be possibly supplied to the pair of overlapping sections of the channel region 415D. Accordingly, unintentional electron movement is less likely to be caused in the channel region 415D and the TFT 415 can be operated appropriately. The second light blocking section 422 overlaps the third light blocking section 44.

### Other Embodiments

The present technology is not limited to the embodiments described in the above descriptions and drawings. The following embodiments may be included in the technical scope of the present technology.

(1) The configuration of the fifth embodiment may be combined with the configuration of the second embodiment. Namely, the second light blocking section that is a portion of the fourth metal film may be separated into the separated second light blocking sections and the number of separation may be equal to the number of the pixels that are arranged in the X-axis direction.

(2) The configuration of the fifth embodiment may be combined with the configuration of the third embodiment. Namely, the second light blocking section that is a portion of the fourth metal film may be separated into the separated second light blocking sections and the number of separation may be about one-third of the number of the pixels that are arranged in the X-axis direction.

(3) The configuration of the fifth embodiment may be combined with the configuration of the fourth embodiment. Namely, the second light blocking section that is a portion of the fourth metal film may be separated into the separated second light blocking sections and the number of separation may be about one-sixth of the number of the pixels that are arranged in the X-axis direction.

(4) In the first to fourth embodiments, the second light blocking section that is a portion of the first metal film has the light blocking function. However, the second light blocking section may be electrically connected to the gate line and the scanning signal transmit through the gate line may be supplied to the second light blocking section. Accordingly, an electric field is applied to the channel region of the TFT from the second light blocking section that is a portion of the first metal film additionally from the gate electrode that is a portion of the second metal film. Therefore, the flowing amount of electrons is preferably increased.

(5) Other than the second to fourth embodiments, the specific forming area of the separated second light blocking sections in the X-axis direction may be altered as appropriate. For example, the separated second light blocking section may be formed to extend over two, four, five, or seven pixels. The separated second light blocking section may be formed to extend over three or more display pixels.

(6) In each of the above embodiments, the second light blocking section is formed to extend over an entire area of the TFT. However, the second light blocking section may not overlap a part of the TFT. In such a configuration, the second light blocking section that is a portion of the first metal film preferably overlaps a section of the channel region overlapping the gate electrode.

(7) Other than each of the above embodiments, the specific planar arrangement of the spacers may be altered as appropriate. In such a case, the second light blocking section is preferably disposed to overlap the spacers but may not be limited thereto.

(8) Other than each of the above embodiments, the specific arrangement sequence of the red pixel, the green pixel, and the blue pixel forming the display pixel (the red color filter, the green color filter, and the blue color filter forming the color filter) may be altered as appropriate.

(9) In each of the above embodiments, the light blocking film of the first light blocking section is made of material having photosensitivity but may be made of non-photosensitive material.

(10) In each of the above embodiments, the light blocking film of the first light blocking section may be patterned with the photolithography method but may be formed with a printing method such as the silk screen method.

(11) Other than each of the above embodiments, the specific structure of the TFT may be altered as appropriate. Specifically, the number of overlapping sections of the channel region of the TFT and the gate line may be one, three or more. The connection electrode that is a portion of the third metal film may not be included and the drain region of the TFT may be directly connected to the pixel electrode through the contact hole.

(12) Other than each of the above embodiments, the display mode of the liquid crystal panel may be TN mode, VA mode, or IPS mode.

(13) Other than each of the above embodiments, the specific planar shape or the specific number of slits included in the pixel electrode may be altered as appropriate.

(14) In each of the above embodiments, the slits are formed in the pixel electrode but may be formed in the common electrode.

(15) In each of the above embodiments, the first transparent electrode film forms the common electrode and the second transparent electrode film forms the pixel electrode. However, the first transparent electrode film may form the pixel electrode and the second transparent electrode film may form the common electrode.

(16) In each of the above embodiments, the liquid crystal display device includes a transmission type liquid crystal panel; however, the liquid crystal display device may include a reflection type liquid crystal panel or a transflective type liquid crystal panel.

(17) In each of the above embodiments, the TFs are arrayed in a matrix in planar arrangement but may be arranged in a zig-zag planar arrangement manner.

(18) In each of the above embodiments, the semiconductor film is a silicon thin film but may be made of amorphous silicon or oxide semiconductor.

(19) In each of the above embodiments, the liquid crystal panel is described as the embodiments. However, other types of display panels (e.g., organic EL panels, electrophoretic display panels (EPD), and micro electro mechanical system (MEMS) display panels) are also included in the scope of the present technology.

(20) In each of the above embodiments, the liquid crystal display device that used for a head-mounted display is described but may be used for other usages. The screen size of the liquid crystal panel or the arrangement pitch of the pixels may be altered as appropriate.

1. A display device comprising:
a first substrate;
a second substrate that is disposed opposite the first substrate;
pixels arranged in a matrix within a plate surface of the first substrate and the second substrate;
a first line disposed on the second substrate and extending in a first direction along the plate surface;
a first light blocking section disposed on the first substrate and between the pixels that are next to each other in the first direction and extending in a second direction that is along the plate surface and crosses the first direction; and
a second light blocking section disposed on the second substrate and between the pixels that are next to each other in the second direction, extending in the first direction, and overlapping the first line.

2. The display device according to claim 1, further comprising a second line disposed on the second substrate and extending in the second direction, wherein
the first light blocking section is provided to overlap the second line.

3. The display device according to claim 2, further comprising a thin film transistor disposed on the second substrate and connected to the first line and the second line, wherein
the second light blocking section overlaps at least a portion of the thin film transistor.

4. The display device according to claim 3, wherein
the thin film transistor includes
a gate electrode connected to the first line,
a source region connected to the second line,
a channel region that is included in a layer lower than the gate electrode such that a portion thereof overlaps the gate electrode via an insulation film therebetween and connected to the source region, and
a drain region connected to an opposite side of the channel region from a source region side of the channel region, and
the second light blocking section is disposed to overlap at least the channel region of the thin film transistor and included in a layer lower than the channel region.

5. The display device according to claim 3, wherein
each of the pixels includes a color filter disposed on the first substrate, and a pixel electrode that is disposed on the second substrate to overlap the color filter and connected to the thin film transistor, and
the second light blocking section is disposed to overlap a connecting section of the thin film transistor and the pixel electrode.

6. The display device according to claim 1, further comprising a spacer that is between the first substrate and the second substrate and keeps a space therebetween, wherein
the second light blocking section overlaps the spacer.

7. The display device according to claim 1, wherein the second light blocking section has a non-separated structure and extends in the first direction and parallel to the first line.

8. The display device according to claim 1, wherein the second light blocking section includes separated second light blocking sections that are arranged in the first direction.

9. The display device according to claim 8, wherein the second light blocking section is disposed such that a length of one of the separated second light blocking sections is equal to an arrangement pitch of the pixels in the first direction.

10. The display device according to claim 8, wherein
the pixels include a red pixel exhibiting red, a green pixel exhibiting green, and a blue pixel exhibiting blue,
the red pixel, the green pixel, and the blue pixel that are continuously arranged in the first direction configure a display pixel, and
the second light blocking section is disposed such that a length of one of the separated second light blocking sections in the first direction matches an integral multiple of an arrangement pitch of display pixels in the first direction.

11. The display device according to claim 10, wherein the second light blocking section is disposed such that a length of one of the separated second light blocking sections in the first direction matches the arrangement pitch of the display pixels in the first direction.

12. The display device according to claim 8, wherein the second light blocking section is disposed such that a separation position of the separated second light blocking sections overlaps the first light blocking section.
